(19) United States
(12) Patent Application Publication
(10) Pub. No.: US 2012/0009526 A1
(43) Pub. Date: Jan. 12, 2012

(54) Method of Forming Fine Patterns

(75) Inventor: Dae Woo Kim, Yongin-si (KR)

(73) Assignee: HYNIX SEMICONDUCTOR INC., Icheon-si (KR)

(21) Appl. No.: 12/945,418

(22) Filed: Nov. 12, 2010

(30) Foreign Application Priority Data
Jul. 9, 2010 (KR) 2010-66488

(51) Int. Cl. G03F 7/20

(52) U.S. Cl. 430/324

(57) ABSTRACT

A method of forming fine patterns comprises forming a first auxiliary layer having an acid diffusion rate on an underlying layer, forming a light-transmitting second auxiliary layer having a slower acid diffusion rate than the first auxiliary layer on the first auxiliary layer, exposing respective regions of the first and second auxiliary layers to generate acid in the exposed regions of the first and second auxiliary layers, diffusing the acid using a baking process so that diffusion of the acid is faster in the first auxiliary layer than in the second auxiliary layer, removing acid diffusion regions in the first and second auxiliary layers to form first and second auxiliary patterns, the second auxiliary pattern being wider width than the first auxiliary pattern, filling the removed regions of the first auxiliary layer with material for a hard mask, and removing the material for a hard mask exposed between the second auxiliary patterns to form hard mask patterns on sidewalls of the first auxiliary patterns.

### CROSS-REFERENCE TO RELATED APPLICATION

Priority to Korean patent application number 10-2010-0066488 filed on Jul. 9, 2010, the entire disclosure of which is incorporated by reference herein, is claimed.

### BACKGROUND

An exemplary embodiment relates generally to a method of forming the fine patterns of a semiconductor device and, more particularly, to a method of forming patterns each finer than an exposure resolution limit.

The patterns of a semiconductor device are typically formed using a photolithography process. The photolithography process is performed by exposing a photoresist layer formed on an underlying layer (i.e., a layer to be etched) and developing the photoresist layer. A photoresist pattern is formed on the underlying layer through the photolithography process.

The photoresist pattern is used as an etch mask when the patterns of the semiconductor device are patterned. Accordingly, the size of the photoresist pattern serves as a factor in determining the size of the patterns of the semiconductor device.

The size of the photoresist pattern is determined by exposure resolution. Thus, the magnitude of reduction in the size of the photoresist pattern is limited by a limit in the exposure resolution. Consequently, a reduction in the size of the patterns of the semiconductor device is limited. However, there is a need for a procedure for forming a pattern finer than the exposure resolution to increase the degree of integration of semiconductor devices.

### BRIEF SUMMARY

An exemplary embodiment relates to a method of forming patterns finer than an exposure resolution.

A method of forming fine patterns according to an aspect of the disclosure comprises forming a first auxiliary layer having an acid diffusion rate on an underlying layer, forming a light-transmitting second auxiliary layer having a slower acid diffusion rate than the first auxiliary layer on the first auxiliary layer, exposing respective regions of the first and second auxiliary layers to generate acid in the exposed regions of the first and second auxiliary layers, diffusing the acid using a baking process so that diffusion of the acid is faster in the first auxiliary layer than in the second auxiliary layer, removing acid diffusion regions in the first and second auxiliary layers to form first and second auxiliary patterns, the second auxiliary pattern being wider width than the first auxiliary pattern, filling the removed regions of the first auxiliary layer with material for a hard mask, and removing the material for a hard mask exposed between the second auxiliary patterns to form hard mask patterns on sidewalls of the first auxiliary patterns.

The method preferably further includes removing the first and second auxiliary patterns after forming the hard mask patterns.

The first auxiliary layer preferably comprises a mixture including at least one of a photo acid generator (PAG) and a thermal acid generator (TAG), light-absorbing resin to absorb light from a light source, and a cross-linked polymer. The cross-linked polymer is de-cross-linked by the acid and becomes soluble in a developer for removing the acid diffusion regions.

The second auxiliary layer preferably comprises a photoresist layer. Additives for activating the diffusion of the acid, as compared with the second auxiliary layer, preferably are mixed in the first auxiliary layer.

Both sidewalls of each of the second auxiliary patterns preferably protrude farther than both sidewalls of each of the first auxiliary patterns. The sidewall of the second auxiliary pattern preferably protrudes farther than the sidewall of the first auxiliary pattern by a width of the first auxiliary pattern. The sidewall of the second auxiliary pattern preferably protrudes farther than the sidewall of the first auxiliary pattern by a width of the hard mask pattern. A gap between the first auxiliary patterns preferably is three times a width of the first auxiliary pattern.

The material for a hard mask preferably has an etch rate that is different from the etch rate of material for the first and second auxiliary patterns. The materials for a hard mask preferably comprise a mixture including carbon.

### BRIEF DESCRIPTION OF THE DRAWINGS

FIGS. 1A to 1E are cross-sectional views illustrating a method of forming fine patterns according to an exemplary embodiment of this disclosure.

### DESCRIPTION OF EMBODIMENT

An exemplary embodiment of the disclosure is describe in detail below with reference to the accompanying drawings. The drawing figures are provided to allow those having ordinary skill in the art to understand the scope of the embodiment of the disclosure.

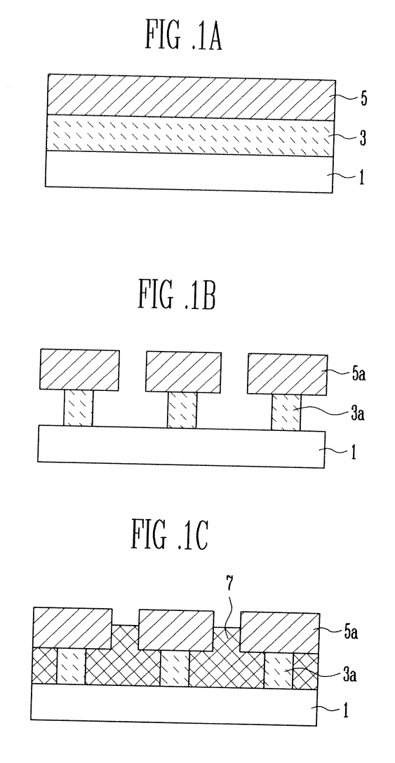

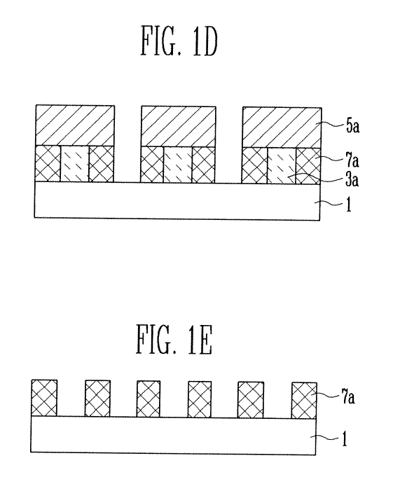

FIGS. 1A to 1E are cross-sectional views illustrating a method of forming fine patterns according to an exemplary embodiment of this disclosure.

Referring to FIG. 1A, a first auxiliary layer 3 and a second auxiliary layer 5 are stacked over an underlying layer 1 (i.e., a layer to be etched).

The first auxiliary layer 3 and the second auxiliary layer 5 preferably are made of materials including a photo acid generator (PAG), which can generate acid through exposure to light. Further, it is preferred that the layers 3 and 5 are made of materials that can be removed in a development process because of acid generated in exposure portions. Also, the second auxiliary layer 5 preferably is made of material that can transmit a light source so that light radiated from an upper portion of the second auxiliary layer 5 can be radiated to the first auxiliary layer 3 via the second auxiliary layer 5. Further, the first auxiliary layer 3 preferably has higher solubility for a developer in a development process than does the second auxiliary layer 5. To this end, additives for activating the diffusion of acid in the first auxiliary layer 3, as compared with the second auxiliary layer 5, can be added to the first auxiliary layer 3. Accordingly, the diffusion rate of acid resulting from heat or light is slower in the second auxiliary layer 5 than in the first auxiliary layer 3.

For example, the second auxiliary layer 5 can be formed of a photoresist preferably comprising a mixture, including a resin that transmits a light source, a photo acid generator (PAG), and a thermal acid generator (TAG). Further, the first auxiliary layer 3 can comprise a developer-soluble bottom anti-reflective coating (D-BARC) layer preferably comprising a mixture including at least one of a photo acid generator (PAG) and a thermal acid generator (TAG), a light-absorbing resin to absorb light from a light source, and a cross-linked polymer de-cross-linked by acid to become soluble in a developer.

The underlying layer 1 preferably comprises a material for a hard mask pattern, used as an etch mask when the patterns of a semiconductor device are patterned, or a material for the patterns of a semiconductor device.

Referring to FIG. 1B, first auxiliary patterns 3a are formed by removing regions of the first auxiliary layer 3, and second auxiliary patterns 5a are formed by removing regions of the second auxiliary layer 5. The second auxiliary patterns 5a are formed over the first auxiliary patterns 3a and each is wider than an associated first auxiliary pattern 3a. Here, since both sidewalls of the second auxiliary pattern 5a protrudes farther from than both sidewalls of the first auxiliary pattern 3a, an undercut phenomenon is generated by the first and second auxiliary patterns 3a, 5a.

The method of forming the first and second auxiliary patterns 3a, 5a is described in detail below.

First, regions of the first auxiliary layer 3 and regions of the second auxiliary layer 5 are exposed to light passing through a reticle (not shown). The reticle has a transparent substrate and light-shielding patterns formed on the transparent substrate. The light-shielding patterns define the respective exposure regions of the first auxiliary layer and the second auxiliary layer. Here, a line width of the light-shielding pattern formed in the reticle preferably is larger than a line width of the pattern of a semiconductor device. Meanwhile, to form fine patterns, an exposure apparatus for immersion, having a light source of ArF 193 nm, preferably is used in an exposure process.

Acid is generated in the exposure regions of the first auxiliary layer and the second auxiliary layer through the above-described exposure process.

Next, a post-exposure bake (PEB) process is performed to diffuse the acid generated in the respective exposure regions of the first auxiliary layer and the second auxiliary layer. The diffusion of acid is faster in the first auxiliary layer than in the second auxiliary layer because of a difference in the respective materials constituting the first auxiliary layer and the second auxiliary layer. Accordingly, the width of a region into which the acid has been diffused in the second auxiliary layer is narrower than the width of a region into which the acid has been diffused in the first auxiliary layer. A de-cross-linking reaction is generated in the respective acid diffusion regions of the first and second auxiliary layers because of the acid, and the acid diffusion regions thus become soluble.

Next, the respective acid diffusion regions of the first and second auxiliary layers are dissolved and removed by a development process using a developer, such as tetra-methyl-ammonium hydroxide (TMAH), for example. Consequently, the first and second auxiliary patterns 3a, 5a remain.

Since the widths of the first and second auxiliary layers dissolved by the developer are different depending on the difference between the widths of the acid diffusion regions in the development process, the removed regions of the first and second auxiliary layers have different widths. More particularly, the width of a removed region of the first auxiliary layer, having a relatively wide acid diffusion region, is wider than the width of a removed region of the second auxiliary layer. Accordingly, after the development process, the second auxiliary pattern 5a can have a wider line width than the first auxiliary pattern 3a.

Referring to FIG. 10, the space between the first auxiliary patterns 3a (i.e., the region from which the first auxiliary layer has been removed) is filled with materials for a multi-function hard mask (MFHM) 7 (hereinafter referred to as ‘the materials for a hard mask’). Here, the materials for a hard mask 7 can be formed up to the height of portions in which the second auxiliary patterns 5a are formed so that the region from which the first auxiliary layer has been removed can be sufficiently filled.

The materials for a hard mask 7 can be selected depending on the thickness and type of the underlying layer 1. Furthermore, the materials for a hard mask 7 preferably are materials having a high etch selectivity for the first and second auxiliary patterns 3a, 5a. That is, the materials for a hard mask 7 preferably have a different etch rate from the first and second auxiliary patterns 3a, 5a. Furthermore, the materials for a hard mask 7 preferably are materials that can be coated. The materials for a hard mask 7 preferably include a mixture containing carbon.

Meanwhile, since the second auxiliary pattern 5a is wider than the first auxiliary pattern 3a, both sidewalls of the second auxiliary pattern 5a protrude farther than both sidewalls of the first auxiliary pattern 3a. Accordingly, the materials for a hard mask 7 to fill the space between the first auxiliary patterns 3a can also be formed in some lower regions of the second auxiliary patterns 5a that protrude farther than the first auxiliary patterns 3a.

Referring to FIG. 1D, the materials for a hard mask exposed between the second auxiliary patterns 5a are removed using the second auxiliary patterns 5a as an etch mask, thereby forming hard mask patterns 7a on the sidewalls of the first auxiliary patterns 3a. Here, each of the hard mask patterns 7a can have a line width narrower than the exposure resolution limit because the line width is defined by a difference in the line width between the first and second auxiliary patterns 3a, 7a, which is determined by the difference in the degree of acid diffusion in the first and second auxiliary layers.

Next, the first and second auxiliary patterns 3a, 5a are removed, and so only the hard mask patterns 7a remain over the underlying layer 1 as shown in FIG. 1E. Accordingly, the pattern of a semiconductor device can be formed with a line width narrower than the exposure resolution limit by patterning the underlying layer 1 using the hard mask patterns 7a as an etch mask.

As described above, in accordance with this disclosure, the first and second auxiliary patterns can be formed with different widths using a difference in the acid diffusion rate in the first and second auxiliary layers. Furthermore, the hard mask patterns, each having a line width narrower than the exposure resolution limit, can be formed on the sidewalls of the first auxiliary patterns using a difference in the line width of the first and second auxiliary patterns. In case where the method of forming fine patterns according to this disclosure is used, fine patterns, each having about 20 nm, can be formed.

Meanwhile, when forming hard mask patterns each having a line width narrower than the exposure resolution limit, a spacer forming process can be used. A method of forming the hard mask patterns using spacers is described in detail below. First, the spacers are formed on the sidewalls of auxiliary patterns formed using a photoresist pattern. Here, the spacers preferably are formed by depositing an oxide layer or a nitride layer so that the space between the auxiliary patterns is not filled, and then performing an etch process such as an etch-back process. In this case, when the oxide layer or the nitride layer is deposited, there is a problem in that a step coverage characteristic must be taken into consideration. Furthermore, a slant is formed at an upper portion of the spacer formed by the etch process, such as an etch-back process. Accordingly, if a patterning process is performed using the spacers, there is a problem in that patterns formed through the spacers can have an asymmetrical structure because the thicknesses of the spacers are not uniformly formed because of the slant at the upper portion.

In this disclosure, to solve the above problem, a gap between the first auxiliary patterns, a gap between the second auxiliary patterns, and a difference in the line width between the first and second auxiliary patterns are controlled by quantitatively controlling a difference in the acid diffusion rate between the first and second auxiliary layers. Accordingly, the hard mask patterns can be formed with a uniform line width and gap. Furthermore, in this disclosure, the step coverage problem needs not to be taken into consideration because the materials for a hard mask are used to fill the space between the first auxiliary patterns. Furthermore, in this disclosure, the problem that patterns are formed to have an asymmetrical structure can be improved because a process, such as an etch-back process, is not used.

In accordance with the disclosure, the acid diffusion rate between the first and second auxiliary layers is controlled so that regions soluble in a developer in the first and second auxiliary layers have different widths. Accordingly, T-shaped auxiliary patterns, each having a stack structure of the first auxiliary pattern and the second auxiliary pattern having a wider width than the first auxiliary pattern, can be formed. Next, in this disclosure, the materials for a hard mask are filled between the T-shaped auxiliary patterns, and the materials for a hard mask exposed between the second auxiliary patterns are then removed. Accordingly, the hard mask patterns, each having a line width narrower than the exposure resolution limit, can be formed on the sidewalls of the first auxiliary patterns. By patterning the patterns of a semiconductor device using the above hard mask patterns as an etch mask, patterns each having a narrower line width than the exposure resolution limit can be formed.

What is claimed is:

1. A method of forming fine patterns, comprising:
forming a first auxiliary layer having an acid diffusion rate on an underlying layer;
forming a light-transmitting second auxiliary layer having a slower acid diffusion rate than the first auxiliary layer on the first auxiliary layer;
exposing respective regions of the first and second auxiliary layers to generate acid in the exposed regions of the first and second auxiliary layers;
diffusing the acid using a baking process so that diffusion of the acid is faster in the first auxiliary layer than in the second auxiliary layer;
removing acid diffusion regions in the first and second auxiliary layers to form first and second auxiliary patterns, the second auxiliary pattern being wider width than the first auxiliary pattern;
filling the removed regions of the first auxiliary layer with material for a hard mask; and
removing the material for a hard mask exposed between the second auxiliary patterns to form hard mask patterns on sidewalls of the first auxiliary patterns.

2. The method of claim 1, further comprising removing the first and second auxiliary patterns after forming the hard mask patterns.

3. The method of claim 1, wherein the first auxiliary layer comprises a mixture including at least one of a photo acid generator (PAG) and a thermal acid generator (TAG), light-absorbing resin, and a cross-linked polymer.

4. The method of claim 3, wherein the cross-linked polymer is de-cross-linked by the acid and becomes soluble in a developer for removing the acid diffusion regions.

5. The method of claim 1, wherein the second auxiliary layer comprises a photoresist layer.

6. The method of claim 1, wherein the first auxiliary layer comprises additives for activating the diffusion of the acid as compared with the second auxiliary layer.

7. The method of claim 1, wherein the first and second auxiliary patterns each have two sidewalls, and both sidewalls of each of the second auxiliary patterns protrude farther than both sidewalls of each of the first auxiliary patterns.

8. The method of claim 7, wherein the sidewalls of the second auxiliary pattern protrudes farther than the sidewalls of the first auxiliary pattern by a width of the first auxiliary pattern.

9. The method of claim 7, wherein the sidewalls of the second auxiliary pattern protrude farther than the sidewalls of the first auxiliary pattern by a width of the hard mask pattern.

10. The method of claim 1, wherein a gap between the first auxiliary patterns is three times a width of the first auxiliary pattern.

11. The method of claim 1, wherein the material for a hard mask has a different etch rate than materials for the first and second auxiliary patterns.

12. The method of claim 11, wherein the material for a hard mask comprises a mixture including carbon.
